(19) United States
(12) Patent Application Publication
(10) Pub. No.: US 2020/0203666 A1
(43) Pub. Date: Jun. 25, 2020

(54) ORGANIC LIGHT EMITTING DIODE DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Jie YANG, Wuhan, Hubei (CN); Ming ZHANG, Wuhan, Hubei (CN)

(21) Appl. No.: 16/462,231

(22) PCT Filed: Nov. 22, 2018
(86) PCT No.: PCT/CN2018/116842

§ 371 Date: May 19, 2019

(30) Foreign Application Priority Data
Oct. 26, 2018 (CN) 201811255154.X

(51) Int. Cl. H01L 51/52

(52) U.S. Cl. CPC H01L 51/5271; H01L 51/5275

(57) ABSTRACT

An organic light emitting diode (OLED) display panel includes a package structure. The package structure includes at least one reflective combined layer configured to reflect ultraviolet rays. The at least one reflective combined layer includes a first reflective sub-layer and a second reflective sub-layer disposed on the first reflective sub-layer. Materials of the first reflective sub-layer and the second reflective sub-layer are same, and refractive indexes of the first reflective sub-layer and the second reflective sub-layer are different. This improves a reflection performance of the at least one reflective combined layer on ultraviolet light.

### FIELD OF INVENTION

The present disclosure relates to the field of display technologies, and more particularly to an organic light emitting diode (OLED) display panel.

### BACKGROUND OF INVENTION

In organic light emitting diode (OLED) display panels, OLED materials are mostly organic and active small molecules, which are sensitive to water and oxygen, and have high performance requirements for blocking water and oxygen in a package. In addition, under an action of energy (such as light) other than electricity, the OLED materials can absorb the energy to cause a degradation of material, this leads to a color decay of a picture. Products without ultraviolet protection can be found to be obviously bluish-purple and a display performance thereof is distorted when the product is displayed in white light after 80 hours of ultraviolet irradiation. Small and medium-sized panel display devices such as mobile phones will inevitably need to be used under sunlight, therefore it is very important to effectively improve an ultraviolet light resistance of the panels.

### SUMMARY OF INVENTION

An embodiment of the present disclosure provides an organic light emitting diode (OLED) display panel to solve the technical problem that a current OLED display panel has a weak ultraviolet light resistance and causes distortion of a display performance of the panel.

An embodiment of the present disclosure provides an organic light emitting diode (OLED) display panel including an organic light emitting layer and a package structure disposed on the organic light emitting layer. The package structure includes at least one reflective combination layer configured to reflect ultraviolet rays. The at least one reflective combined layer includes a first reflective sub-layer and a second reflective sub-layer disposed on the first reflective sub-layer. Materials of the first reflective sub-layer and the second reflective sub-layer are same, and refractive indexes of the first reflective sub-layer and the second reflective sub-layer are different, such that the at least one reflective combined layer is configured to reflect the ultraviolet rays. The materials of the first reflective sub-layer and the second reflective sub-layer are both SiOₓN_{y}, the refractive index of the first reflective sub-layer ranges between 1.7 and 2.0, and the refractive index of the second reflective sub-layer ranges between 1.3 and 1.5.

In an embodiment of the present disclosure, in the at least one reflective combined layer, the first reflective sub-layer is disposed adjacent to a side of the organic light emitting layer, and an oxygen content of the first reflective sub-layer is less than a nitrogen content of the first reflective sub-layer.

In an embodiment of the present disclosure, the package structure includes a buffer layer disposed on the at least one reflective combined layer, and in the at least one reflective combined layer, the second reflective sub-layer is disposed adjacent to a side of the buffer layer, an oxygen content of the second reflective sub-layer is greater than a nitrogen content of the second reflective sub-layer.

In an embodiment of the present disclosure, a thickness of the first reflective sub-layer is greater than or equal to a thickness of the second reflective sub-layer.

In an embodiment of the present disclosure, a thickness of the first reflective sub-layer and a thickness of the second reflective sub-layer both range between 50 nm and 100 nm.

In an embodiment of the present disclosure, the at least one reflective combined layer is used as an inorganic layer of the package structure, and a thickness of the inorganic layer ranges between 0.5 μm and 1.5 μm.

In an embodiment of the present disclosure, the package structure includes a plurality of the reflective combination layers, and at least a portion of the reflective combination layers is configured to reflect different wavelengths of light.

In an embodiment of the present disclosure, the package structure further includes a buffer layer disposed on the at least one reflective combined layer and a barrier layer disposed on the buffer layer, the barrier layer is one of the first reflective sub-layer, the second reflective sub-layer, and a combined layer of the first reflective sub-layer and the second reflective sub-layer.

An embodiment of the present disclosure provides an organic light emitting diode (OLED) display panel including an organic light emitting layer and a package structure disposed on the organic light emitting layer. The package structure includes at least one reflective combination layer configured to reflect ultraviolet rays. The at least one reflective combined layer includes a first reflective sub-layer and a second reflective sub-layer disposed on the first reflective sub-layer. Materials of the first reflective sub-layer and the second reflective sub-layer are same, and refractive indexes of the first reflective sub-layer and the second reflective sub-layer are different, such that the at least one reflective combined layer is configured to reflect the ultraviolet rays.

In an embodiment of the present disclosure, the materials of the first reflective sub-layer and the second reflective sub-layer are both SiOₓN_{y}.

In an embodiment of the present disclosure, in the at least one reflective combined layer, the first reflective sub-layer is disposed adjacent to a side of the organic light emitting layer, and an oxygen content of the first reflective sub-layer is less than a nitrogen content of the first reflective sub-layer.

In an embodiment of the present disclosure, the package structure includes a buffer layer disposed on the at least one reflective combined layer, and in the at least one reflective combined layer, the second reflective sub-layer is disposed adjacent to a side of the buffer layer, an oxygen content of the second reflective sub-layer is greater than a nitrogen content of the second reflective sub-layer.

In an embodiment of the present disclosure, the refractive index of the first reflective sub-layer ranges between 1.7 and 2.0, and the refractive index of the second reflective sub-layer ranges between 1.3 and 1.5.

In an embodiment of the present disclosure, a thickness of the first reflective sub-layer is greater than or equal to a thickness of the second reflective sub-layer.

In an embodiment of the present disclosure, a thickness of the first reflective sub-layer and a thickness of the second reflective sub-layer both range between 50 nm and 100 nm.

In an embodiment of the present disclosure, the at least one reflective combined layer is used as an inorganic layer of the package structure, and a thickness of the inorganic layer ranges between 0.5 μm and 1.5 μm.

In an embodiment of the present disclosure, the package structure includes a plurality of the reflective combination layers, and at least a portion of the reflective combination layers is configured to reflect different wavelengths of light.

In an embodiment of the present disclosure, the package structure further includes a buffer layer disposed on the at least one reflective combined layer and a barrier layer disposed on the buffer layer, the barrier layer is one of the first reflective sub-layer, the second reflective sub-layer, and a combined layer of the first reflective sub-layer and the second reflective sub-layer.

In an embodiment of the present disclosure, the package structure further includes a buffer layer disposed on the at least one reflective combined layer and a barrier layer disposed on the buffer layer, material of the barrier layer is one of SiNₓ, Al₂O₃, and TiO₂.

Compared with the OLED display panel of the prior art, the OLED display panel of the embodiment of the present disclosure provides the first reflective sub-layer and the second reflective sub-layer with different refractive indexes using the same material, and the first reflective sub-layer and the second reflective sub-layer are combined to form the reflective combined layer having a function of reflecting ultraviolet light. On one hand, because the first reflective sub-layer and the second reflective sub-layer are made of the same material for easy preparation using the same equipment, and this saves process steps. On another hand, the combination structure of the first reflective sub-layer and the second reflective sub-layer having different refractive indexes improves a reflection performance of the reflective combined layer on ultraviolet light and solves issues that a current OLED display panel has a weak ultraviolet light resistance and causes distortion of a display performance of the panel.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic structural diagram of an organic light emitting diode (OLED) display panel according to an embodiment of the present disclosure.

### DETAILED DESCRIPTION OF PREFERRED EMBODIMENTS

Referring to the accompanying drawings, in which the same component symbols represent the same components. The following description is based on the specific embodiments of the present disclosure as illustrated, and should not be construed as limiting the specific embodiments that are not described herein.

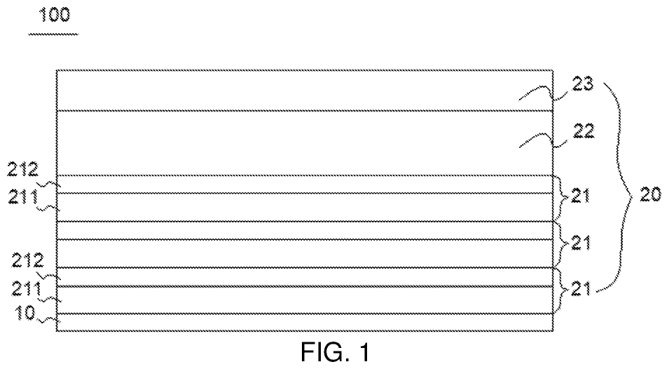

Referring to FIG. 1, an organic light emitting diode (OLED) display panel according to an embodiment of the present disclosure is provided. An embodiment of the present disclosure provides an organic light emitting diode (OLED) display panel 100 including an organic light emitting layer 10 and a package structure 20 disposed on the organic light emitting layer 10. The package structure 20 includes at least one reflective combination layer 21 configured to reflect ultraviolet rays, a buffer layer 22 disposed on the at least one reflective combined layer 21, and a barrier layer 23 disposed on the buffer layer 23.

The at least one reflective combined layer 21 includes a first reflective sub-layer 211 and a second reflective sub-layer 212 disposed on the first reflective sub-layer 211. Materials of the first reflective sub-layer 211 and the second reflective sub-layer 212 are same, and refractive indexes of the first reflective sub-layer 211 and the second reflective sub-layer 212 are different, such that the at least one reflective combined layer 21 is configured to reflect the ultraviolet rays.

In the embodiment, the first reflective sub-layer 211 and the second reflective sub-layer 212 having different refractive indexes are formed using the same material, and the first reflective sub-layer 211 and the second reflective sub-layer 212 are combined to form the reflective combined layer 21 having a function of reflecting ultraviolet light.

On one hand, because the first reflective sub-layer 211 and the second reflective sub-layer 212 are made of the same material for easy preparation using the same equipment, and this saves process steps. On another hand, the combination structure of the first reflective sub-layer 211 and the second reflective sub-layer 212 having different refractive indexes improves a reflection performance of the reflective combined layer 21 on ultraviolet light, thereby improving a display performance and a service life of the OLED display panel.

In the present embodiment, the package structure 20 includes a plurality of layers of reflective combination layers 21, wherein at least a portion of the reflective combination layers 21 reflect different wavelengths of light. Because ultraviolet light has a wavelength of between 10 nm and 400 nm, a combined structure using different reflective combined layers 21 reflects different ultraviolet wavelengths, further improving a reflection performance of the OLED display panel on the ultraviolet light, thereby improving the display performance and the service life thereof.

In addition, the reflective combination layer 21 is used as part of the package structure, which saves process steps of separately forming the inorganic layer of the package structure of the OLED display panel.

In an embodiment of the present disclosure, the materials of the first reflective sub-layer 211 and the second reflective sub-layer 212 are both SiOₓN_{y}. It should be noted that x and y are coefficient values, for example, x=1, y=2, and the like. SiOₓN_{y} has certain water-oxygen barrier properties and adhesion properties, and is suitable for the package structure of the OLED display panel. Further, by changing a content ratio of oxygen and nitrogen in SiOₓN_{y}, and forming films with different refractive indexes, the reflective combined layer configured to reflect ultraviolet light is formed.

It is understood that, in the embodiment, materials of the first reflective sub-layer and the second reflective sub-layer may be a transparent inorganic material having a certain adhesion property with water and oxygen barrier properties.

In details, in the reflective combined layer 211, the first reflective sub-layer 211 is disposed adjacent to a side of the organic light emitting layer 10, and an oxygen content of the first reflective sub-layer 211 is less than a nitrogen content thereof.

When the reflective combined layer 21 has a plurality of layers, a first layer of the reflective combined layers 21 is formed on the organic light emitting layer 10, and the buffer layer 22 is formed on a last layer of the reflective combined layers 21. In details, the first reflective sub-layer 211 is formed on the organic light emitting layer 10, the second reflective sub-layer 212 is formed on the first reflective sub-layer 211, and the buffer layer 22 is formed on the second reflective sub-layer 212 of the last layer of the reflective combined layers 21.

Because the oxygen content of the first reflective sub-layer 211 is less than the nitrogen content thereof, that is, the nitrogen content of the first reflective sub-layer 211 is greater than the oxygen content thereof, such that the first reflective sub-layer 211 has excellent water-oxygen barrier properties to prevent water and oxygen from entering the organic light emitting layer 10. Because an oxygen content of the second reflective sub-layer 212 is greater than a nitrogen content thereof, that is, the oxygen element content of the second reflective sub-layer 212 is greater than the nitrogen content thereof, such that the second reflective sub-layer 212 has excellent organic/inorganic adhesion properties and is easily bonded to the buffer layer 22 to improve a stability and a sealing performance of the package structure 20.

In this embodiment, the refractive index of the first reflective sub-layer ranges between 1.7 and 2.0, and the refractive index of the second reflective sub-layer ranges between 1.3 and 1.5. The refractive indexes of the first reflective sub-layer 211 and the second reflective sub-layer 212 are both performed under a specific condition that the first reflective sub-layer 211 has excellent water-oxygen barrier properties and the second reflective sub-layer 212 has excellent adhesion properties. Such an arrangement can satisfy functions of reflecting ultraviolet light and packaging the light emitting organic layer 10 by the package structure 20 using only one process, thereby saving process steps and reducing costs. Optionally, the refractive index of the first reflective sub-layer is 1.7, 1.75, 1.8, 1.85, 1.9, 1.95, or 2.0. The refractive index of the second reflective sub-layer 212 is 1.3, 1.35, 1.4, 1.45, and 1.5.

In the embodiment, a thickness of the first reflective sub-layer 211 is greater than or equal to a thickness of the second reflective sub-layer 212. Because a function of the package structure 20 is mainly to prevent external water and oxygen from entering an interior of the OLED display panel 100 to etch the organic light emitting layer 10, such an arrangement ensures water-oxygen barrier properties of the package structure 20.

In addition, a thickness of the first reflective sub-layer 211 and a thickness of the second reflective sub-layer 212 both range between 50 nm and 100 nm.

It should be noted that when the first reflective sub-layer 211 and the second reflective sub-layer 212 satisfy λ=2(n₁d₁+n₂d₂), a corresponding wavelength has a reflection action. λ (lambda) is a wavelength of an incident light (that is, a wavelength of a reflected light), n₁ is a high refractive index, that is, the refractive index of the first reflective sub-layer 211, n₂ is a low refractive index, that is, the refractive index of the second reflective sub-layer 212, d₁ is the thickness of the first reflective sub-layer, and d₂ is the thickness of the second reflective sub-layer. Therefore, it is possible to reflect ultraviolet light of any wavelength by adjusting the refractive indexes and the thicknesses of the first reflective sub-layer and the second reflective sub-layer.

In the embodiment, at least one reflective composite layer 21 is used as the inorganic layer of the package structure 20, and a thickness of the inorganic layer ranges between 0.5 μm and 1.5 μm. Such an arrangement ensures a flexible reliability of the package structure 20.

In the embodiment, the barrier layer 23 is one of the first reflective sub-layer 211, the second reflective sub-layer 212, and a combined layer of the first reflective sub-layer 211 and the second reflective sub-layer 212. Such an arrangement can have a protective function and further improve the reflection performance of the OLED display panel 100 against ultraviolet light. It is understood that, material of the barrier layer may also be one of SiNₓ, Al₂O₃, and TiO₂.

In an embodiment of the present disclosure, the package structure further includes a buffer layer disposed on the at least one reflective combined layer and a barrier layer disposed on the buffer layer, material of the barrier layer is one of SiNₓ, Al₂O₃, and TiO₂.

A manufacturing process of the OLED display panel of the embodiment includes steps as follows.

First, a substrate is provided, and a thin film transistor array layer and an organic light emitting layer 10 are sequentially formed on the substrate.

Then, a first reflective sub-layer 211 is formed on the organic light emitting layer 10 by a PECVD (plasma enhanced chemical vapor deposition), wherein the first reflective sub-layer 211 is formed by adjusting a flow ratio and an energy of a film forming gas.

Next, a second reflective sub-layer 212 is formed on the first reflective sub-layer 211 by the PECVD to form a reflective combined layer 21 in combination with the first reflective sub-layer 211, wherein the second reflective sub-layer 212 is formed by adjusting a flow ratio and an energy of a film forming gas.

Next, the first reflective sub-layer 211 is formed on the second reflective sub-layer 212, such as a loop, until all the reflective combined layers 21 have reached a desired thickness.

Finally, a buffer layer 22 and a barrier layer 23 are sequentially formed on the second reflective sub-layer 212.

This completes the manufacturing process of the embodiment.

Compared with the OLED display panel of the prior art, the OLED display panel of the embodiment of the present disclosure provides the first reflective sub-layer and the second reflective sub-layer with different refractive indexes using the same material, and the first reflective sub-layer and the second reflective sub-layer are combined to form the reflective combined layer having a function of reflecting ultraviolet light. On one hand, because the first reflective sub-layer and the second reflective sub-layer are made of the same material for easy preparation using the same equipment, and this saves process steps. On another hand, the combination structure of the first reflective sub-layer and the second reflective sub-layer having different refractive indexes improves a reflection performance of the reflective combined layer on ultraviolet light and solves issues that a current OLED display panel has a weak ultraviolet light resistance and causes distortion of a display performance of the panel.

In summary, it should be noted that those of ordinary skill in the art can make a variety of improvements and substitutions on the premise of not deviating from the technical solutions and technical concepts of the present disclosure, and these improvements and substitutions should be encompassed within the protection scope of the present disclosure.

1. An organic light emitting diode (OLED) display panel, comprising:
an organic light emitting layer; and
a package structure disposed on the organic light emitting layer;
wherein the package structure comprises at least one reflective combination layer configured to reflect ultraviolet rays;
wherein the at least one reflective combined layer comprises a first reflective sub-layer and a second reflective sub-layer disposed on the first reflective sub-layer, wherein materials of the first reflective sub-layer and the second reflective sub-layer are same, and refractive indexes of the first reflective sub-layer and the second reflective sub-layer are different, such that the at least one reflective combined layer is configured to reflect the ultraviolet rays;
wherein the materials of the first reflective sub-layer and the second reflective sub-layer are both SiOₓN_{y}, the refractive index of the first reflective sub-layer ranges between 1.7 and 2.0, and the refractive index of the second reflective sub-layer ranges between 1.3 and 1.5.

2. The OLED display panel according to claim 1, wherein in the at least one reflective combined layer, the first reflective sub-layer is disposed adjacent to a side of the organic light emitting layer, and an oxygen content of the first reflective sub-layer is less than a nitrogen content of the first reflective sub-layer.

3. The OLED display panel according to claim 1, wherein the package structure comprises a buffer layer disposed on the at least one reflective combined layer, and in the at least one reflective combined layer, the second reflective sub-layer is disposed adjacent to a side of the buffer layer, an oxygen content of the second reflective sub-layer is greater than a nitrogen content of the second reflective sub-layer.

4. The OLED display panel according to claim 1, wherein a thickness of the first reflective sub-layer is greater than or equal to a thickness of the second reflective sub-layer.

5. The OLED display panel according to claim 1, wherein a thickness of the first reflective sub-layer and a thickness of the second reflective sub-layer both range between 50 nm and 100 nm.

6. The OLED display panel according to claim 1, wherein the at least one reflective combined layer is used as an inorganic layer of the package structure, and a thickness of the inorganic layer ranges between 0.5 μm and 1.5 μm.

7. The OLED display panel according to claim 1, wherein the package structure comprises a plurality of the reflective combination layers, wherein at least a portion of the reflective combination layers is configured to reflect different wavelengths of light.

8. The OLED display panel according to claim 1, wherein the package structure further comprises a buffer layer disposed on the at least one reflective combined layer and a barrier layer disposed on the buffer layer, the barrier layer is one of the first reflective sub-layer, the second reflective sub-layer, and a combined layer of the first reflective sub-layer and the second reflective sub-layer.

9. An organic light emitting diode (OLED) display panel, comprising:
an organic light emitting layer; and
a package structure disposed on the organic light emitting layer;
wherein the package structure comprises at least one reflective combination layer configured to reflect ultraviolet rays;
wherein the at least one reflective combined layer comprises a first reflective sub-layer and a second reflective sub-layer disposed on the first reflective sub-layer, wherein materials of the first reflective sub-layer and the second reflective sub-layer are same, and refractive indexes of the first reflective sub-layer and the second reflective sub-layer are different, such that the at least one reflective combined layer is configured to reflect the ultraviolet rays.

10. The OLED display panel according to claim 9, wherein the materials of the first reflective sub-layer and the second reflective sub-layer are both SiOₓN_{y}.

11. The OLED display panel according to claim 10, wherein in the at least one reflective combined layer, the first reflective sub-layer is disposed adjacent to a side of the organic light emitting layer, and an oxygen content of the first reflective sub-layer is less than a nitrogen content of the first reflective sub-layer.

12. The OLED display panel according to claim 10, wherein the package structure comprises a buffer layer disposed on the at least one reflective combined layer, and in the at least one reflective combined layer, the second reflective sub-layer is disposed adjacent to a side of the buffer layer, an oxygen content of the second reflective sub-layer is greater than a nitrogen content of the second reflective sub-layer.

13. The OLED display panel according to claim 9, wherein the refractive index of the first reflective sub-layer ranges between 1.7 and 2.0, and the refractive index of the second reflective sub-layer ranges between 1.3 and 1.5.

14. The OLED display panel according to claim 9, wherein a thickness of the first reflective sub-layer is greater than or equal to a thickness of the second reflective sub-layer.

15. The OLED display panel according to claim 9, wherein a thickness of the first reflective sub-layer and a thickness of the second reflective sub-layer both range between 50 nm and 100 nm.

16. The OLED display panel according to claim 9, wherein the at least one reflective combined layer is used as an inorganic layer of the package structure, and a thickness of the inorganic layer ranges between 0.5 μm and 1.5 μm.

17. The OLED display panel according to claim 9, wherein the package structure comprises a plurality of the reflective combination layers, wherein at least a portion of the reflective combination layers is configured to reflect different wavelengths of light.

18. The OLED display panel according to claim 9, wherein the package structure further comprises a buffer layer disposed on the at least one reflective combined layer and a barrier layer disposed on the buffer layer, the barrier layer is one of the first reflective sub-layer, the second reflective sub-layer, and a combined layer of the first reflective sub-layer and the second reflective sub-layer.
